(19) United States
(12) Patent Application Publication
(10) Pub. No.: US 2013/0292704 A1
(43) Pub. Date: Nov. 7, 2013

(54) SILICON CARBIDE STRUCTURE AND METHOD OF PRODUCING THE SAME

(71) Applicant: Norihide Imagawa, Tokyo (JP)

(72) Inventor: Norihide Imagawa, Tokyo (JP)

(73) Assignee: Tis & Partners Co., Ltd., Tokyo (JP)

(21) Appl. No.: 13/882,740

(22) PCT Filed: Nov. 2, 2011
(86) PCT No.: PCT/JP2011/006148

§ 371 Date: Jul. 16, 2013

(30) Foreign Application Priority Data
Nov. 2, 2010 (JP) 2010-246862
Oct. 17, 2011 (JP) PCT/JP2011/005782

(51) Int. Cl. H01L 29/16; H01L 21/02

(52) U.S. Cl. CPC H01L 29/1608; H01L 21/02529
USPC 257/77; 438/478

(57) ABSTRACT

To provide a block-constituted structure of silicon carbide for use as a construction material, and a method of producing the block-constituted silicon carbide structure, which method realizes thorough compatibility with the natural environment by consuming carbon dioxide and releasing oxygen during the block production process. The silicon carbide structure is formed by injecting carbon dioxide into silicon-oxide-rich silica sand sealed a form to react therewith and form the resulting silicon carbide into a block of fixed shape, and is waterproofed for use as a construction material.

### RELATED APPLICATIONS

This application is a §371 application from PCT/JP2011/006148 filed Nov. 2, 2011, which claims priority from Japanese Patent Application No. 2010-246862 filed Nov. 2, 2010 and International Application NO. PCT/JP2011/005782 filed Oct. 17, 2011, each of which is herein incorporated by reference in its entirety.

### TECHNICAL FIELD

The present invention relates to a silicon carbide structure formed by reacting carbon dioxide with silicon oxide, particularly to a silicon carbide structure for use as a block-constituted construction material of fixed shape formed by charging silica sand containing silicon oxide into a form and injecting carbon dioxide into the silica sand to react therewith, and to a method of producing the same.

### BACKGROUND ART

Recent rapid advances in construction technology extend to the development and utilization of construction materials exhibiting excellent strength, abrasion resistance, chemical resistance, stress relaxation characteristics, elastic recovery characteristics, and other properties. For example, Japanese Patent Publication (A) No. H7-41343 teaches an artificial light-weight aggregate formed by using a caking clay to granulate fine powder of limestone/glass containing an added silicon carbide expanding agent or the like and then baking the result at a low temperature. This provides an artificial light-weight aggregate of low weight and high hardness, and suggests the possibility of use in materials for constructing highrise buildings and other such structures.

Japanese Patent Publication (A) No. 2007-39887 describes a construction material formed of an epoxy resin containing dispersed fine hollow aggregate and plastic fiber, plus dispersed modified amine, titanium oxide and the like when necessary. This makes thick coating easy to perform while maintaining excellent light weight property and enables provision of a construction material with high strength.

Further, Japanese Patent Publication (A) No. 2009-228003 sets out a technology related to a construction material using an epoxy resin composition. The composition is said to enable efficient, low-cost supply of a raw material that is low in water absorbency and high in heat resistance.

However, construction materials utilizing the aforesaid technologies are liable to burden the environment both during production and in the course of disassembly and decomposition. A particular issue in this regard is that they involve release of carbon dioxide, which is counterproductive from the viewpoint of the need to protect the environment by minimizing the emission of carbon dioxide. They can hardly be called excellent in this aspect. In an age when the prevention of global warming is viewed as an unrivaled challenge, the development of construction materials that are environmentally friendly from the viewpoint of restraining the release of carbon dioxide is considered essential.

With consideration to the burden on the environment when vinyl chloride resin is incinerated and decomposed, Japanese Patent Publication (A) No. 2002-265742 discloses an alternative compound that makes it possible to realizes provision of materials for construction and other purposes that are excellent in rigidity, strength, impact resistance, weatherability, chemical resistance, abrasion resistance, scratch resistance, indentation resistance, depression recovery property, and printability, and also excellent in heat resistance, stress relaxation characteristics, shape conformability, and workability during shaping.

Although this publication does indeed offer a technology sensitive to the natural environment, its sensitivity is inadequate from the viewpoint of whether embracing a conceptual focus on aggressively enhancing the natural environment. Of particular note is that from the viewpoint of carbon dioxide emission it can hardly be said to offer thorough restraint.

Development is therefore desired of a construction material that not only exhibits properties like rigidity, strength and impact resistance, but is also ultimately friendly to the natural environment in the course of production and so on.

### PRIOR ART DOCUMENTS

### Patent Documents

Patent Document 1: Japanese Patent Publication (A) No. H7-41343

Patent Document 2: Japanese Patent Publication (A) No. 2007-39887

Patent Document 3: Japanese Patent Publication (A) No. 2009-228003

Patent Document 4: Japanese Patent Publication (A) No. 2002-265742

### DISCLOSURE OF THE INVENTION

### Problem to be Overcome by the Invention

In order to resolve the foregoing issues, the present invention provides a block-constituted structure of silicon carbide for use as a construction material, and a method of producing the block-constituted silicon carbide structure, which method realizes thorough compatibility with the natural environment by consuming carbon dioxide and releasing oxygen during the block production process.

### Means for Solving the Problem

In order to achieve the aforesaid object, the silicon carbide structure according to the present invention is constituted by injecting carbon dioxide into silicon-oxide-rich silica sand sealed a form to react therewith and form the resulting silicon carbide into a block of fixed shape.

Moreover, the block is configured for use as a construction material.

In addition, the block-constituted silicon carbide structure is constituted to maintain water-tightness by applying a waterproof coating or other waterproofing to part or all of the block surface.

Further, the block is a block-constituted silicon carbide structure formed using a form of desired shape.

In addition, the block-constituted silicon carbide structure is constituted in a finished shape for use as it is as a compression-resistive silicon carbide structure, and constituted for use as a silicon carbide structure having material tensile strength by providing the interior and side (bonding portion) of the block-constituted silicon carbide structure with a material having tensile resistance and/or a metal material.

Further, the method of producing the silicon carbide structure comprises steps of sealing silica sand containing silicon oxide into a form and injecting carbon dioxide into the silica sand to react therewith, thereby forming a silicon carbide block of fixed shape usable as a construction material.

Moreover, the form is one for forming a wall, pillar or foundation portion of a building, and the form for forming the wall, pillar or foundation of the building is constituted to be directly installed at the wall, pillar or foundation.

Further, the silicon carbide structure is constituted by injecting carbon dioxide into silica sand containing silicon oxide sealed in a form to react therewith and additionally injecting and/or applying a hardener comprising organic material, thereby forming a block of fixed shape.

It is also constituted by injecting carbon dioxide and silicate of soda (sodium silicate) into silica sand containing silicon oxide sealed in a form to react therewith and form silicon carbide produced by the reaction into a block of fixed shape.

Moreover, the silicon carbide structure is constituted by forming silicon carbide injected and/or coated with a hardener into a block of fixed shape.

In addition, the hardener comprises epoxy resin or urethane.

Further, it is constituted by injecting carbon dioxide and silicate of soda (sodium silicate) into coal ash containing silicon oxide sealed in a form to react therewith and solidifying silicon carbide produced by the reaction, thereby forming a block of fixed shape.

Further, the silicon carbide structure is constituted by injecting carbon dioxide and silicate of soda (sodium silicate) into coal ash containing silicon oxide sealed in a form, and additionally injecting and/or applying a hardener comprising organic material, thereby forming a block of fixed shape.

In addition, the hardener comprises epoxy resin, urethane, or lacquer.

### Effect of the Invention

Being constituted as set out in the foregoing, the present invention has the following effects.

1. Since the carbon dioxide is injected into silica sand containing silicon oxide that is sealed in a frame, it is possible to form a silicon carbide structure of any shape or size that maintains a fixed shape that does not easily deform. Further, owing to the fact that the silicon carbide is formed by reacting silica sand with injected carbon dioxide, the substances formed following the reaction include oxygen in addition the silicon carbide, so that an eco-friendly block-constituted silicon carbide structure excellent in strength and heat resistance can be provided.

2. As the block exhibits advantageous features such as hardness, heat resistance and chemical stability, it enables provision of an eco-friendly material suitable for use as a construction material.

3. Since part or all of the surface of the block-constituted silicon carbide structure is subjected to waterproof coating, it maintains water-tightness and enables provision of a highly stable silicon carbide structure and construction material.

4. Since the shape of the frame of the block-constituted silicon carbide structure can be configured as desired, a silicon carbide structure and construction material matched to any purpose or shape can be provided.

5. While the block-constituted silicon carbide structure can itself be used as a finished structure, it can also be equipped with reinforcing steel bars or other metal material for use as a structure that needs tensile strength. It can therefore be utilized as a material maintaining stability even under tension and compression applied from any direction.

6. The method of producing the block-constituted silicon carbide structure is simple, and an eco-friendly production method that releases no carbon dioxide can be provided merely by the process of sealing silica sand in a form and injecting carbon dioxide into the silica sand.

7. Moreover, when the form used is installed directly at a wall, pillar or foundation portion of a building, a construction material can be easily formed merely by assembling the form, so that construction material hauling cost can be reduced and the load on the natural environment occurring during hauling can also be reduce.

8. Further, after the block has been solidified by injecting carbon dioxide into silica sand, it is injected and/or coated with a hardener comprising organic material (epoxy resin, urethane or the like), whereby a strong block can be provided that is highly resistant to deformation and can withstand impacts from the outside.

9. Furthermore, the block is injected with silicate of soda together with carbon dioxide, making it possible to constitute a still stronger block.

10. Additional injection or application of a hardener enables provision of a deformation resistant block that also has a strong surface and can stand up under actual use.

11. Similar effects can be realized regardless of whether the hardener used is epoxy resin or, alternatively, urethane, lacquer or the like.

12. Moreover, formation of the block using high silica-content coal ash enables effective resource utilization owing to the use of a material treated as industrial waste as a raw material.

13. Further, the block is additionally injected with silicate of soda and injected and/or coated with a hardener, whereby it is possible to provide a block that is strong and resistant to deformation.

14. A strong and deformation resistant block can be provided by using epoxy resin, urethane, lacquer or the like as hardener used for the block.

### BRIEF EXPLANATION OF THE DRAWINGS

FIG. 1 is a perspective view of a form for forming a silicon carbide structure 1 constituted of a rectangular parallelepiped block.

FIG. 2 is a perspective view of a structure-formation form 10 equipped with a carbon dioxide-injection lid 31.

FIG. 3 is a perspective view of a cylindrical structure-formation form 12.

FIG. 4 is a cross-section of FIG. 3.

FIG. 5 is a perspective view of a carbon dioxide-injection lid 34 used with an injection hole-perforated cylindrical structure-formation form 14.

FIG. 6 is a cross-section of FIG. 5.

FIG. 7 is a perspective view of a silicon carbide structure 1 constituted of a waterproofed block

FIG. 8 is perspective view of a silicon carbide structure 1 constituted of a block and equipped with a tensile resistance-effective material 60.

FIG. 9 is a perspective view of a silicon carbide structure 70 comprising comb teeth.

FIG. 10 is a perspective view showing the silicon carbide structure 70 comprising comb teeth in a stacked state.

FIG. 11 is a perspective view of another embodiment of the silicon carbide structure 70 comprising comb teeth.

FIG. 12 is a perspective view of a silicon carbide structure 70 comprising a single comb tooth.

FIG. 13 is a cross-sectional view showing another embodiment of the method of producing the silicon carbide structure.

FIG. 14 is a perspective view showing another embodiment of the method of producing the silicon carbide structure.

### BEST MODE FOR WORKING THE INVENTION

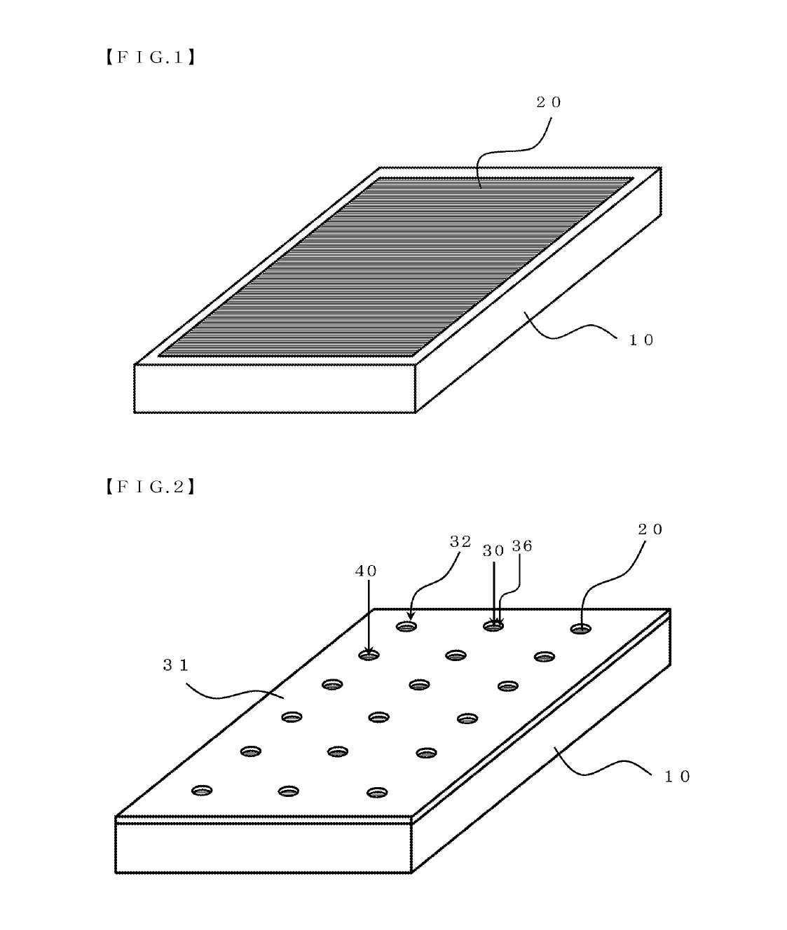

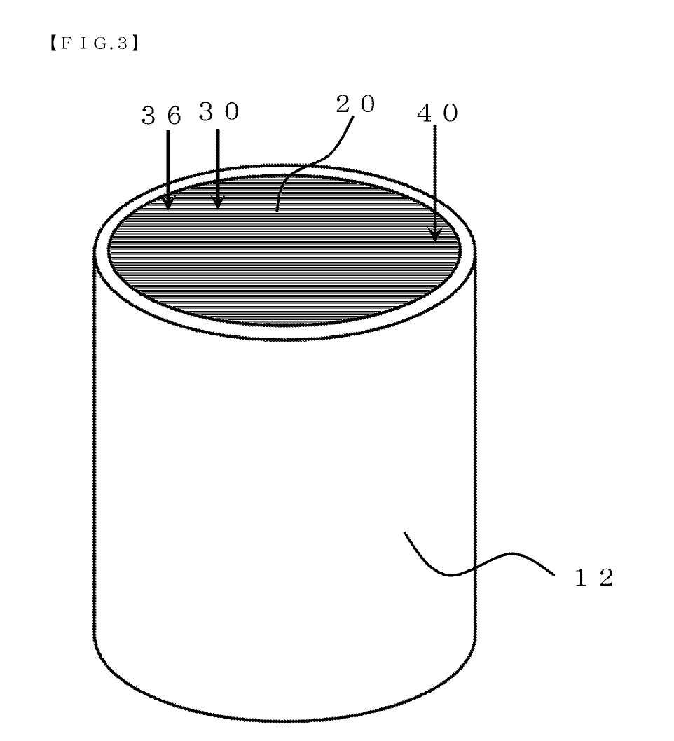

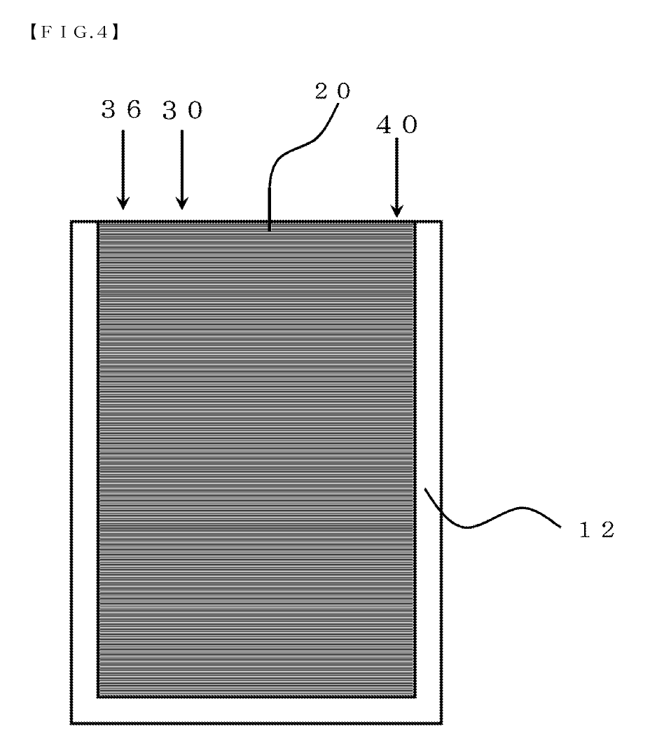

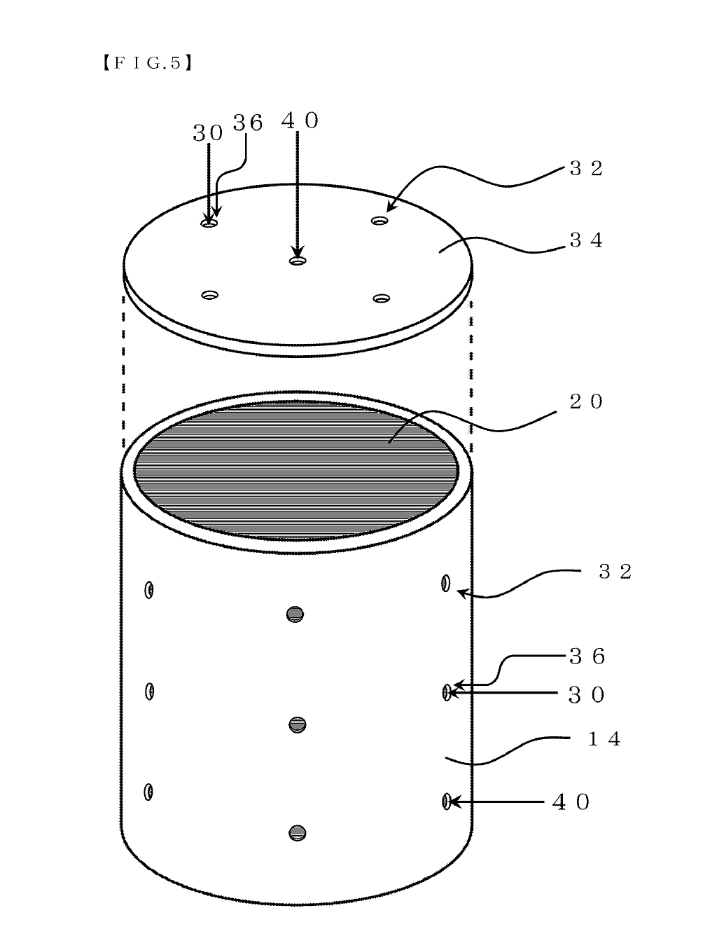

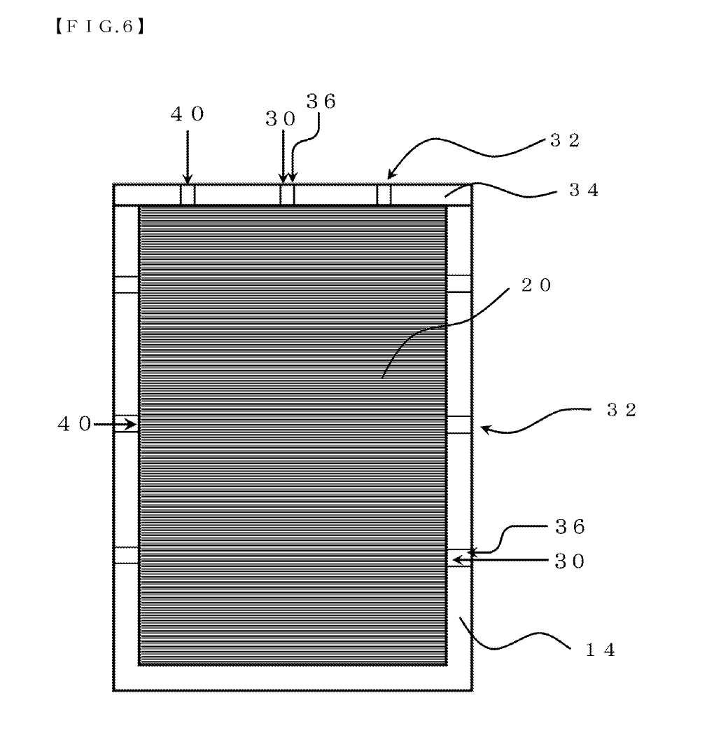

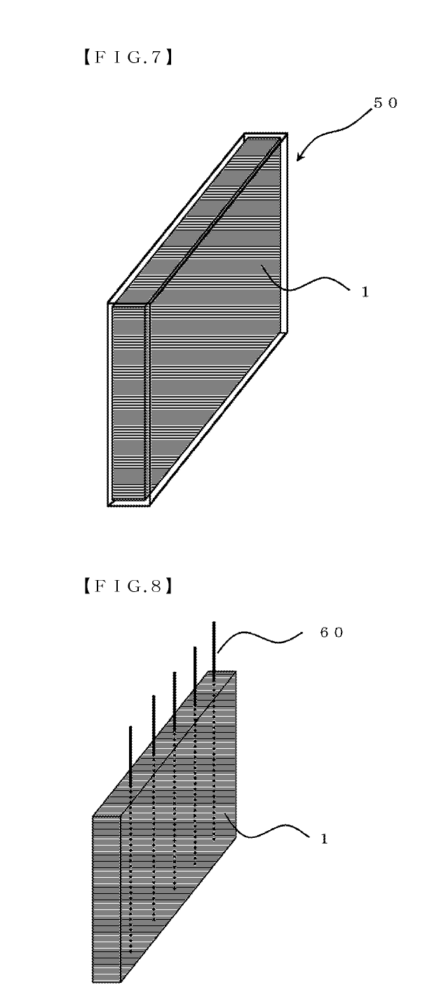

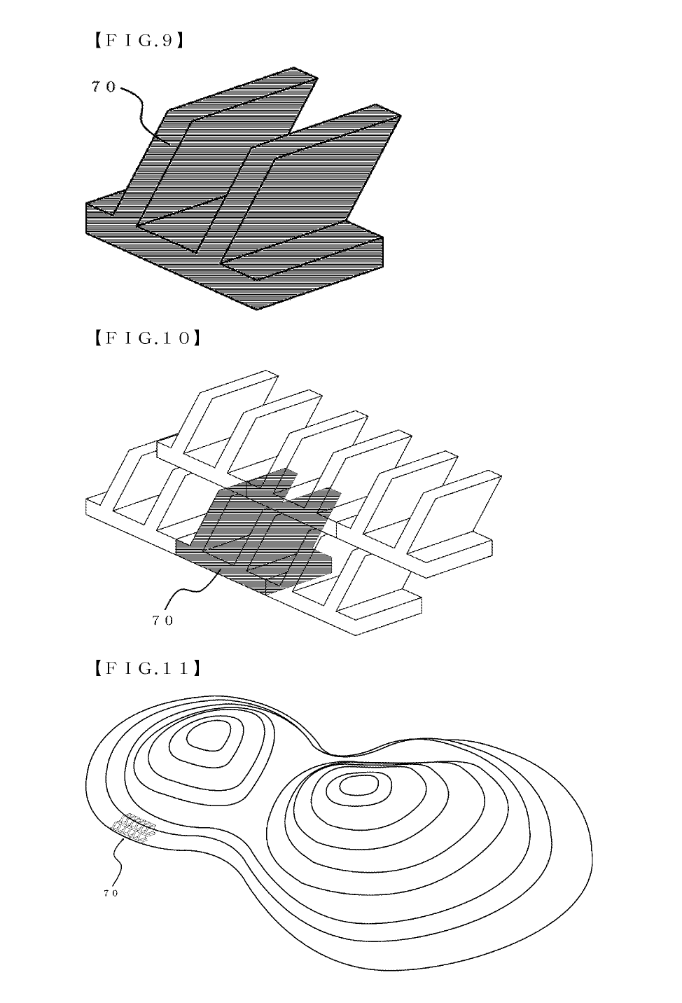

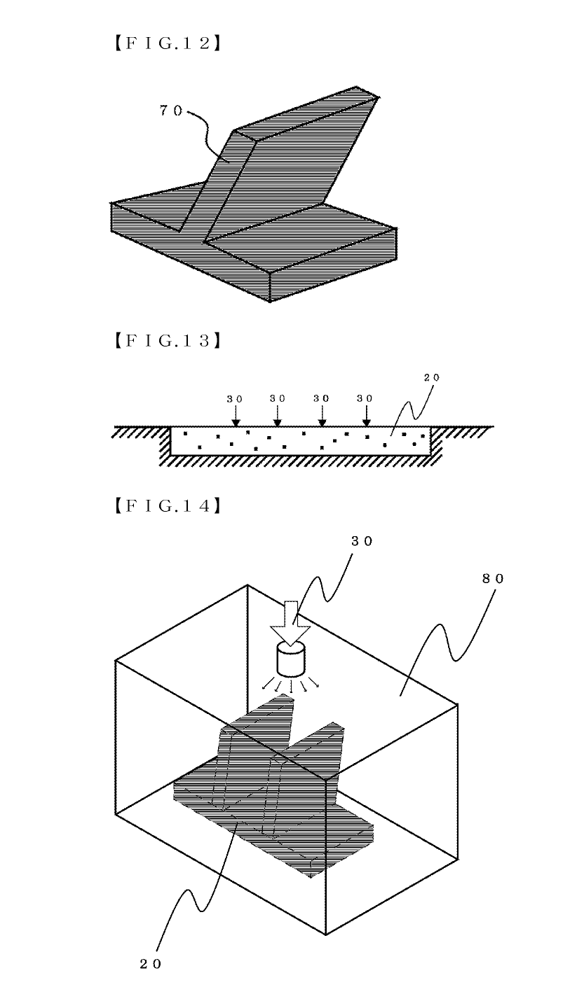

The silicon carbide structure according to the present invention is explained below based on embodiments shown in the drawings. FIG. 1 is a perspective view of a form for forming a silicon carbide structure 1 constituted of a rectangular parallelepiped block, and FIG. 2 is a perspective view of a structure-formation form 10 equipped with a carbon dioxide-injection lid 31. FIG. 3 is a perspective view of a cylindrical structure-formation form 12, and FIG. 4 is a cross-section of FIG. 3. FIG. 5 is a perspective view of a carbon dioxide-injection lid 34 used with an injection hole-perforated cylindrical structure-formation form 14, and FIG. 6 is a cross-section of FIG. 5. FIG. 7 is a perspective view of a silicon carbide structure 1 constituted of a waterproofed block. FIG. 8 is perspective view of a block-constituted silicon carbide structure 1 equipped with a tensile resistance-effective material 60. FIG. 9 is a perspective view of a silicon carbide structure 70 comprising comb teeth, FIG. 10 is a perspective view showing the silicon carbide structure 70 comprising comb teeth in a stacked state, and FIG. 11 is a perspective view of another embodiment of the silicon carbide structure 70 comprising comb teeth. FIG. 12 is a perspective view of a silicon carbide structure 70 comprising a single comb tooth, FIG. 13 is a cross-sectional view showing another embodiment of the method of producing the silicon carbide structure, and FIG. 14 is a perspective view showing another embodiment of the method of producing the silicon carbide structure.

The silicon carbide structure 1 according to the present invention is produced using a structure-formation form 10, silica sand 20 and carbon dioxide 30, and further waterproofed as necessary using a waterproofing member 50.

The structure-formation form 10, which is used to form the block-constituted silicon carbide structure 1, is a rectangular parallelepiped frame obtained by assembling long panels in parallel.

The shape of the form is not necessarily limited to rectangular parallelepiped. For example, it can as necessary be constituted as a cylindrical structure-formation form 12, as shown in FIG. 3, or be constituted as an injection hole-perforated cylindrical structure-formation form 14, as shown in FIG. 5. Irrespective of whether the cylindrical structure-formation form 12 or the injection hole-perforated cylindrical structure-formation form 14, the silicon carbide structure 1 can be formed by sealing and reacting silica sand 20 therein, and in addition its strength can be increased by applying pressure from above.

The silica sand 20 is sandy matter comprising silicon oxide (SiO2). The silica sand 20 sealed in the form is silicon oxide and is in the state of the silicon carbide structure 1 to be formed into a block prior to reaction. After reaction, it solidifies to become a block composed of the silicon carbide structure 1 to be used as a construction material.

The carbon dioxide 30 is ordinary gaseous carbon dioxide (CO2), and in this invention serves as a medium for forming silicon carbide (SiC) by injection into silicon oxide (SiO2) to produce a reaction therewith, namely, a binding reaction that removes oxygen from the silicon oxide.

The carbon dioxide-injection lid 31 and the carbon dioxide-injection lid for cylindrical shaping 34 are lids used when injecting the carbon dioxide 30 into the silica sand 20, wherein carbon dioxide-injection holes 32 are openings used to inject the carbon dioxide 30 into the silica sand 20.

As shown in FIG. 1, the silica sand 20 is charged into the rectangular parallelepiped-shaped structure-formation form 10. In the embodiment, the form for forming the structure is a rectangular parallelepiped, but it is not limited to this shape and can instead be cubic, cylindrical or the like. Although not a major limitation, it has a size of about 300 mm×900 mm in this embodiment, taking into consideration form stability, ease of fabrication, and ease of transport.

The silica sand 20 is sealed inside the rectangular parallelepiped-shaped structure-formation form 10. At this time, in order to enhance the strength of the block-constituted silicon carbide structure 1, the sealing is preferably implemented under application of pressing force. Further, considering the aesthetic aspect of the block-constituted silicon carbide structure, and for preventing unsteadiness when stacked, measures can be taken to hold the sealed opening portion horizontal after the sealing.

The silica sand 20 is charged into the rectangular parallelepiped-shaped structure-formation form 10, whereafter it is covered with the carbon dioxide-injection lid 31 as shown in FIG. 2. The carbon dioxide-injection lid 31 is provided with openings constituting the carbon dioxide-injection holes 32. The size and number of the carbon dioxide-injection holes 32 are decided as desired. In this embodiment, when the form has the aforesaid size of about 300 mm×900 mm, the diameter of the openings is set at around 10 mm and the number of openings at around 18, out of consideration for the reaction efficiency with the carbon dioxide 30 and dispersion of the carbon dioxide 30 to the exterior.

A carbon dioxide gas cylinder (not shown) or the like is used to inject the carbon dioxide 30 through the carbon dioxide-injection holes 32 into the silica sand 20 sealed inside the rectangular parallelepiped-shaped structure-formation form 10. This causes a chemical reaction that forms silicon carbide, a substance excellent in hardness, heat resistance and chemical resistance, and produces the block-constituted silicon carbide structure 1. Although the time period of injecting the carbon dioxide 30 is arbitrary, in this embodiment, which takes the points of the reaction efficiency with the carbon dioxide 30 and dispersion of the carbon dioxide 30 to the exterior into consideration, the time period of carbon dioxide 30 injection into a form of the aforesaid volume is around 20 sec but can be longer depending on the reaction speed.

The chemical reaction that forms the silicon carbide of the present invention is as follows:

SiO2+CO2→SiC+202.

The chemical reaction occurring during formation of the silicon carbide structure 1 generates oxygen (O2) and releases it into the atmosphere. As a natural environment-friendly chemical reaction occurs by which carbon dioxide (C02 gas) is injected and oxygen released, the formation of the silicon carbide structure 1 constituting a construction material leads to an effect of reducing carbon dioxide.

While not limiting the use of the block-constituted silicon carbide structure 1, the formation method is simple and enables formation of many blocks in a short time. Silicon carbide is itself a substance excellent in chemical stability, so that the body is strong and heat resistant. The chemical reaction is thoroughly eco-friendly even when a large quantity is formed at the same time because what is emitted by the formation is oxygen. Use as a construction material is considered a desirable construction method compatible with carbon dioxide release reduction.

The waterproofing member 50 is installed on the block-constituted silicon carbide structure 1 to prevent adherence of rain and other moisture. Although silicon carbide is by nature a compound with stable properties, such as high melting point and water insolubility, it is conceivable that the block-constituted silicon carbide structure 1 formed by the present invention may include incompletely reacted residual portions. In such case, the block-constituted silicon carbide structure itself might become low in stability with respect to water from the aspect of hardness, and in order to resolve this, the waterproofing member 50 is installed on the block-constituted silicon carbide structure 1.

As shown in FIG. 7, the waterproofing member 50 is applied over portions of the surface of the block-constituted silicon carbide structure 1 that are apt to come in contact with water during use. The raw material used for the waterproofing can be a waterproofing material such as a water proof coating. Although it is desirably applied to cover the whole surface of the block-constituted silicon carbide structure 1, it can instead be provided only at certain portions that come in contact with water. Although the material of the waterproofing member 50 is not particularly specified, when the block-constituted silicon carbide structure 1 is, for example, used as a construction material for an exterior wall, interior wall or the like, an option from the aesthetic viewpoint is to use transparent glass, plastic, acrylic resin or other material that makes the block-constituted silicon carbide structure 1 visible from the outside.

The cylindrical structure-formation form 12 is a form used to form a cylindrical structure. The silica sand 20 is sealed in the cylindrical structure-formation form 12 as shown in FIG. 3, and the strength enhancement by application of pressure from above is also possible in the other embodiments. The silicon carbide structure 1 constituted of a cylindrical block is formed by the reaction occurring when carbon dioxide is injected into the cylindrical structure-formation form 12 using a carbon dioxide gas cylinder or the like. This form can, according to the purpose, be modified from the cylindrical shape of this embodiment into a polygonal cylinder, cube or sphere, for example, so as to enable formation of a block-constituted silicon carbide structure 1 of the desired shape by modifying the shape of the form as desired.

FIG. 5 shows another embodiment, in which the carbon dioxide-injection lid for cylindrical shaping 34 is placed on top of the injection hole-perforated cylindrical structure-formation form 14. In this case, the carbon dioxide-injection lid for cylindrical shaping 34 and the injection hole-perforated cylindrical structure-formation form 14 are provided with the carbon dioxide-injection holes 32. The size of the carbon dioxide-injection holes 32 is arbitrary. In this embodiment, the diameter of the openings is set at around 10 mm, taking into account the reaction efficiency with the carbon dioxide 30 and dispersion of the carbon dioxide 30 to the exterior. The silicon carbide structure 1 constituted of a cylindrical block is formed by the reaction occurring when carbon dioxide 30 is injected through the carbon dioxide-injection holes 32 provided in the carbon dioxide-injection lid for cylindrical shaping 34 and the carbon dioxide-injection holes 32 provided in the injection hole-perforated cylindrical structure-formation form 14 using a carbon dioxide gas cylinder or the like. This form can also be modified from the cylindrical shape into a polygonal cylinder or other shape.

The tensile resistance-effective material 60 is a member used when the block-constituted silicon carbide structure 1 is required to exhibit tensile resistance.

When utilized in a compression-resistive mode displaying resistance against compression, the block-constituted silicon carbide structure 1 is used as it is in the finished shape of the block-constituted silicon carbide structure 1. On the other hand, higher strength is required in a case where twisting, bending or other material tensile strength is necessary, so rather than use the block-constituted silicon carbide structure 1 as it is in the foregoing shape as formed into a rectangular parallelepiped, it is desirable, as shown in FIG. 8, to additionally install the tensile resistance-effective material 60 (e.g., a metal material such as steel reinforcing bar material) inside and at the bonding portion of the block-constituted silicon carbide structure 1. The tensile resistance-effective material 60 suffices so long as it has a hardness of up to around a degree at which the block-constituted silicon carbide structure 1 has resistance against twisting, bending and other material tension, and use of a steel or other metal material or some other reinforcing material is possible. Further, the tensile resistance-effective material 60 is not limited to bar shape, but can be plate-shaped instead. Moreover, it can be installed vertically or horizontally, or be installed both vertically and horizontally.

In another embodiment for constituting the silicon carbide structure 1, the carbon dioxide 30 is injected into the silica sand 20 sealed inside the rectangular parallelepiped-shaped structure-formation form 10, the cylindrical structure-formation form 12, or the injection hole-perforated cylindrical structure-formation form 14. This causes a chemical reaction that forms silicon carbide and produces the block-constituted silicon carbide structure 1. In this regard, it is possible to additionally inject and/or apply a hardener 40 comprising organic material. Although the block-constituted silicon carbide structure 1 is strong enough to maintain a fixed shape even without injecting or applying the hardener 40, it is possible by injecting and/or applying the hardener 40 to strengthen the formed block-constituted silicon carbide structure 1 to make it strong against external pressure and less susceptible to deformation. As this makes firm maintenance of a fixed shape possible, it can be expected to enable use in a broad range of applications in building foundations and other venues requiring robust strength.

In still another embodiment, the injection of the carbon dioxide 30 into the silica sand 20 sealed in one of the aforesaid forms is accompanied by simultaneous injection of silicate of soda 36 (sodium silicate) to react therewith and enable formation of the block-constituted silicon carbide structure 1. Sodium silicate is a water-soluble substance, and this concentrated aqueous solution is a highly viscous liquid called waterglass that is useful as an additive for viscosity adjustment. The injection of the sodium silicate into the silica sand 20 together with the carbon dioxide 30 makes it possible to form the silicon carbide structure 1 to have a still stronger fixed shape. It is also possible to inject and/or apply the hardener 40 comprising organic material into/onto the silicon carbide structure 1. This enables the silicon carbide structure 1 to be formed with high strength and resistance to surface deformation.

Epoxy resin, urethane, lacquer and the like are usable as the hardener 40. Although these resins are considered suitable as materials used in the silicon carbide structure 1 of the present invention from the viewpoint strength and handling, the present invention is not limited thereto and other resins are also usable insofar capable of ensuring strength.

The amount injected and/or applied can be appropriately regulated in accordance with the purpose of the silicon carbide structure 1, but taking into account the importance of the visual impression of persons encountering the silicon carbide structure 1, the amount injected and/or applied is desirably regulated to a level that does not detract from the visual feel of the silica-sand texture displayed by the silicon carbide structure 1.

In another embodiment for constituting the silicon carbide structure 1, coal ash containing silicon oxide is sealed in the frame, and the carbon dioxide 30 and silicate of soda 36 (sodium silicate) are injected into it to react therewith, thereby producing silicon carbide to enable formation of a block of the silicon carbide structure 1 of fixed shape.

The components of coal ash include a large amount of the silicon oxide used in the present invention. These components are currently treated as industrial waste, so that using coal ash as a raw material helps realize effective resource utilization. Moreover, carbon dioxide is used in the production process and no harmful substances are produced after reaction, making it possible to form a structure that is friendly to the natural environment. In addition, the property of being instantaneously formable holds promise for use also as an educational material and a medical material.

The carbon dioxide 30 and silicate of soda 36 (sodium silicate) injected into the coal ash containing silicon oxide chemically react therewith to form sodium metasilicate as one constituent substance. As sodium metasilicate (called “silica gel”) maintains a nearly solid state and has a porous structure, it plays a role as a catalyst. This sodium metasilicate functions to bind the silicon carbide particles, thereby increasing the compressive strength and tensile strength of the silicon carbide structure.

The aforesaid reaction forms sodium carbonate and water in addition to oxygen. As these are not substances that place a load on the natural environment, an eco-friendly structure can be produced.

The silicon carbide structure 1 produced using coal ash containing silicon oxide can additionally be formed with the hardener 40 comprising organic material injected therein or applied to the surface of the formed silicon carbide structure. The surface of silicon carbide structure injected with the hardener can also be coated with the hardener. This enables formation of a still stronger silicon carbide structure 1.

Epoxy resin, urethane, lacquer and the like are usable as the hardener 40. An effect of enhancing the strength of the silicon carbide structure 1 can be expected from lacquer because it is a property of lacquer to harden by binding with oxygen. Moreover, these materials have a property of absorbing water (H₂O) and oxygen (O) contained in the silicon carbide structure 1, which makes it possible to obtain the formed silicon carbide structure 1 with a low water content and thus increase strength from this aspect as well.

It should be noted that the resin used as a hardener in the silicon carbide structure 1 is not limited to those mentioned above and other resins are also usable so long as they are strength-enhancing materials.

With consideration to the visual impression the silicon carbide structure 1, the amount of the hardener 40 injected and/or applied is desirably adjusted so as not to detract from the visual feel of the silica-sand texture displayed by the silicon carbide structure 1.

As illustrated in FIG. 9 to FIG. 11, another possible embodiment is carbide structures 70 comprising comb teeth and deployed in a configuration following contour lines. Here, as shown in FIG. 9, the silicon carbide structure 70 is fabricated to comprise comb teeth in a shape obtained by planting the comb teeth upright on a plate. Then, as shown in FIG. 10, the silicon carbide structures 70 are stacked to point in the height direction with the comb-tooth pairs staggardly arranged. As shown in FIG. 11, a contour line-like structure is completed by stacking in a configuration following contour lines. By this, a strong and stable wall can be built and the interior can be utilized as a space. Although the silicon carbide structure 70 comprising the comb teeth can be constituted with multiple comb teeth as shown in FIG. 9, it is also possible as shown in FIG. 12 to constitute the silicon carbide structure 70 to have only a single comb tooth.

In order to increase the strength of the block-constituted silicon carbide structure 1, the silica sand 20 is charged into the rectangular parallelepiped-shaped structure-formation form 10 and sealed therein under application of pressing force. Coal ash can be sealed in the rectangular parallelepiped-shaped structure-formation form 10 instead of the silica sand 20. After the charging, the sealed opening portion is evenly leveled to horizontal. Next, the carbon dioxide-injection lid 31 is set on top, and a carbon dioxide gas cylinder or the like is used to inject the carbon dioxide 30 through the carbon dioxide-injection holes 32. At this time, the silicate of soda 36 (sodium silicate) can be injected simultaneously. After the carbon dioxide 30 and/or silicate of soda 36 (sodium silicate) has been injected to cause a chemical reaction, the solidified block-constituted silicon carbide structure 1 is taken out of the rectangular parallelepiped-shaped structure-formation form 10. As a result, silicon carbide is formed as a hard substance which is excellent in heat resistance and chemical stability and maintains a fixed shape, whereby the block-constituted silicon carbide structure 1 is formed. The silicon carbide structure 1 can in addition be injected and/or coated with the hardener 40 comprising organic material and hardened before or after removal from the form, thereby forming a hardness reinforced block of fixed shape.

When the cylindrical structure-formation form 12 is used, the silica sand 20 is sealed in the form 12 and strength is increased by applying pressure from above. Coal ash can be sealed in the cylindrical structure-formation form 12 instead of the silica sand 20. Next, a carbon dioxide gas cylinder or the like is used to inject the carbon dioxide 30 through the upper opening of the cylindrical structure-formation form 12. At this time, the silicate of soda 36 (sodium silicate) can be injected simultaneously. After the carbon dioxide 30 and/or silicate of soda 36 (sodium silicate) has been injected to cause a chemical reaction, the solidified block-constituted silicon carbide structure 1 of fixed shape is taken out of the cylindrical structure-formation form 12. In the case of an embodiment in which the carbon dioxide-injection lid for cylindrical shaping 34 is set on top, a carbon dioxide gas cylinder or the like is used to inject the carbon dioxide 30 and/or silicate of soda 36 (sodium silicate) through the carbon dioxide-injection holes 32 provided in the carbon dioxide-injection lid for cylindrical shaping 34 and injection hole-perforated cylindrical structure-formation form 14 to cause a chemical reaction, whereafter the solidified block-constituted silicon carbide structure 1 of fixed shape is taken out of the injection hole-perforated cylindrical structure-formation form 14. As a result, a cylindrical silicon carbide structure 1 of fixed shape is formed. The silicon carbide structure 1 can in addition be injected and/or coated with the hardener 40 comprising organic material and hardened before or after removal from the form.

Since this results in oxygen being formed during the reaction and formation of the cylindrical silicon carbide structure 1, generation of carbon dioxide in the course of forming the silicon carbide structure is prevented and, to the contrary, oxygen is emitted, so that formation of an eco-friendly silicon carbide structure is possible.

When the block-constituted silicon carbide structure 1 is used as a construction material, the rectangular parallelepiped-shaped structure-formation form 10, cylindrical structure-formation form 12 or other form can be installed immediately at a sidewall or other portion of the structure. A wall, pillar, foundation portion or the like of the structure can be formed directly at the construction site, thereby enabling easy supply of construction materials and simultaneous reduction of costs related to the transport of construction materials, while also reducing the load on the natural environment during transport.

Moreover, in another embodiment of the present invention, rather than use the rectangular parallelepiped-shaped structure-formation form or cylindrical structure-formation form, it is possible, as shown in FIG. 13, to embed the silica sand 20 in and level with the ground surface, apply pressing force for strength enhancement, blow the carbon dioxide 30 thereon in the atmosphere so as to solidify and form the silicon carbide structure 1. It also possible to embed coal ash instead of the silica sand 20 in and level with the ground surface and form the solidified silicon carbide structure 1 on the ground surface. This enables easy supply of construction materials and simultaneous reduction of costs related to the transport of construction materials, while also reducing the load on the natural environment during transport.

Further, when injecting carbon dioxide, it is possible, as shown in FIG. 14, to adopt a method of sealing the rectangular parallelepiped-shaped structure-formation form 10, cylindrical structure-formation form 12, injection hole-perforated cylindrical structure-formation form 14 or the like in a sealable container 80, and injecting carbon dioxide from outside the container. As this injects highly concentrated carbon dioxide into the silica sand 20, a stronger silicon carbide structure 1 can be formed. In the case of the silica sand 20 embedded directly in the ground surface, a similar effect can be obtained by enclosing the deposited silica sand 20 to seal it in.

Conceivable uses of the silicon carbide structure 1 of the present invention extend beyond the aforesaid utilizations as land-use construction materials to applications in underwater construction, which are possible owing to the ability to form high-strength waterproof silicon carbide structures. The ability to form strong structures wherever desired also opens the way to ground-improvement applications.

1. A silicon carbide structure characterized in being formed by injecting carbon dioxide into silicon-oxide-rich silica sand sealed in a form to react therewith and form silicon carbide produced by the reaction into a block of fixed shape.

2. A silicon carbide structure according to claim 1, characterized in that the block is used as a construction material.

3. A silicon carbide structure according to claim 1 or 2, characterized in that surfaces of the block are subjected to waterproofing partially or throughout to maintain watertightness of the block.

4. A silicon carbide structure according to any of claims 1 to 3, characterized in that the block is a block formed using a form of desired shape.

5. A silicon carbide structure according to any of claims 1 to 4, characterized in that the block is in a finished block shape for use as it is as a compression-resistive silicon carbide structure, and for use as a silicon carbide structure having material tensile strength is provided internally and at sides (bonding portions) of the block with a material having tensile resistance and/or a metal material.

6. A method of producing a silicon carbide structure characterized in comprising: sealing silicon-oxide-rich silica sand into a form; and injecting carbon dioxide into the silica sand to react therewith, thereby forming a silicon carbide block of fixed shape usable as a construction material.

7. A method of producing a silicon carbide structure according to claim 6, characterized in that the form is one for forming a wall portion of a building, and a form for forming a wall, pillar or foundation of the building is directly installed at the wall, pillar or foundation.

8. A silicon carbide structure characterized in being formed by injecting carbon dioxide into silicon-oxide-rich silica sand sealed in a form to react therewith and additionally injecting and/or applying a hardener comprising organic material, thereby forming a block of fixed shape.

9. A silicon carbide structure characterized in being formed by injecting carbon dioxide and silicate of soda (sodium silicate) into silicon-oxide-rich silica sand sealed in a form to react therewith and form silicon carbide produced by the reaction into a block of fixed shape.

10. A silicon carbide structure according to claim 9, characterized in that the silicon carbide structure is a block of fixed shape formed by injecting and/or applying a hardener into/onto the silicon carbide.

11. A silicon carbide structure according to any of claim 8 or 10, characterized in that the hardener is epoxy resin, urethane or lacquer.

12. A silicon carbide structure characterized in being formed by injecting carbon dioxide and silicate of soda (sodium silicate) into silicon-oxide-rich coal ash sealed in a form to react therewith and solidify silicon carbide produced by the reaction into a block of fixed shape.

13. A silicon carbide structure according to claim 12, characterized in being formed by injecting the carbon dioxide and silicate of soda (sodium silicate) into the silicon-oxide-rich coal ash sealed in the form, and additionally injecting and/or applying a hardener comprising organic material, thereby forming a block of fixed shape.

14. A silicon carbide structure according to claim 13, characterized in that the hardener is epoxy resin, urethane or lacquer.
